(19) United States
(12) Patent Application Publication
(10) Pub. No.: US 2023/0044269 A1
(43) Pub. Date: Feb. 9, 2023

(54) APPARATUS AND METHOD FOR MAGNETIC RESONANCE MATERIAL LOCATOR

(71) Applicant: Matthew Vreeland, Layton, UT (US)

(72) Inventor: Matthew Vreeland, Layton, UT (US)

(21) Appl. No.: 17/385,662

(22) Filed: Jul. 26, 2021

(51) Int. Cl. G01V 3/14; G01R 33/36

(52) U.S. Cl. CPC G01V 3/14; G01R 33/3607; G01R 33/441

(57) ABSTRACT

Systems and methods for locating a substance of interest below the Earth's surface are provided. One embodiment generates a downward directed magnetic pulse using a magnetic field pulse generator, wherein phonon energy is emitted by a plurality of nuclei in response to precession induced into the plurality of nuclei by the magnetic field pulse; detecting the phonon energy with at least one acoustic transducer; communicating a signal corresponding to the detected phonon energy from at least one acoustic transducer to a controller system; analyzing a frequency domain of the signal corresponding to the detected phonon energy at the controller system; comparing the analyzed frequency domain of the signal with the phonon response frequency for the plurality of different substances at the controller system; and identifying a substance when the compared analyzed frequency domain of the signal matches the phonon response frequency for one of the plurality of different substances.

### BACKGROUND OF THE INVENTION

Significant effort has been made to identify and to locate a wide variety of substances beneath the surface of the Earth. Such substances include elements, organic compounds, and inorganic compounds. The substances may be a solid, powder or liquid Earth substances that can be located with digging precision would provide an opportunity for more abundant use of this planet.

Accordingly, there is a need in the arts for improved methods, apparatus, and systems for locating substances below the surface of the Earth with digging precision.

### SUMMARY OF THE INVENTION

Embodiments of the electronic device use history system provide a system and method for locating a substance of interest below the Earth's surface is provided. One embodiment generates a downward directed magnetic pulse using a magnetic field pulse generator, wherein phonon energy is emitted by a plurality of nuclei in response to precession induced into the plurality of nuclei by the magnetic field pulse; detecting the phonon energy with at least one acoustic transducer; generating an acoustic modes by a predetermined magnetic field generated from the Earth's core and a predetermined magnetic pulse generator together these resonant conditions happen at a specific depth that depends on the Earth's magnetic field gradient that is used to identify and locate a specific substance, which vibrates at a specific depth correlated to the magnetic pulse generator which generates precession magnetic dipoles that is absorbed into the natural lattice acoustic energy communicating a signal corresponding to the detected phonon energy from at least one acoustic transducer to a controller system; analyzing a frequency domain of the signal and the Earth's magnetic field gradient corresponding to the detected phonon energy at the controller system; comparing the analyzed frequency domain of the signal with the phonon response frequency for the plurality of different substances at the controller system; and identifying a substance when the compared analyzed frequency domain of the signal matches the phonon response frequency for one of the plurality of different substances.

### BRIEF DESCRIPTION OF THE DRAWINGS

The components in the drawings are not necessarily to scale relative to each other. Like reference numerals designate corresponding parts throughout the several views.

FIG. 1 is a conceptual perspective diagram of a magnetic resonance material locator system.

FIG. 2 is a conceptual side view diagram of a magnetic resonance material locator system.

FIG. 3A is a conceptual diagram of the atomic nuclei an atom with three protons magnetically aligned with the Earth's magnetic field.

FIG. 3B is a conceptual diagram of the atomic nuclei with three protons magnetically realigned in response to magnetic interaction with the generated magnetic field pulse and the Earth's magnetic field 308.

FIG. 4 is a conceptual diagram of magnetic properties of nuclear spins, where energy levels and space quantization are created for nuclei under an external magnetic field.

FIG. 5 is a block diagram of an embodiment of the magnetic resonance material locator system 100.

FIG. 6 is a plot of an example plot of signal strength versus time indicating an example magnet field pulse and the phonon response frequency of the detected acoustic energy.

### DETAILED DESCRIPTION

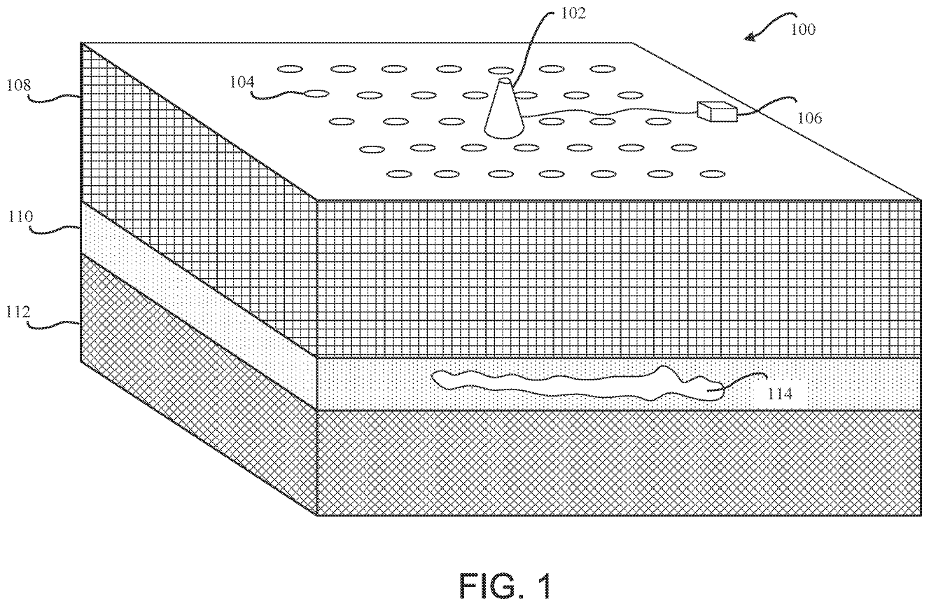

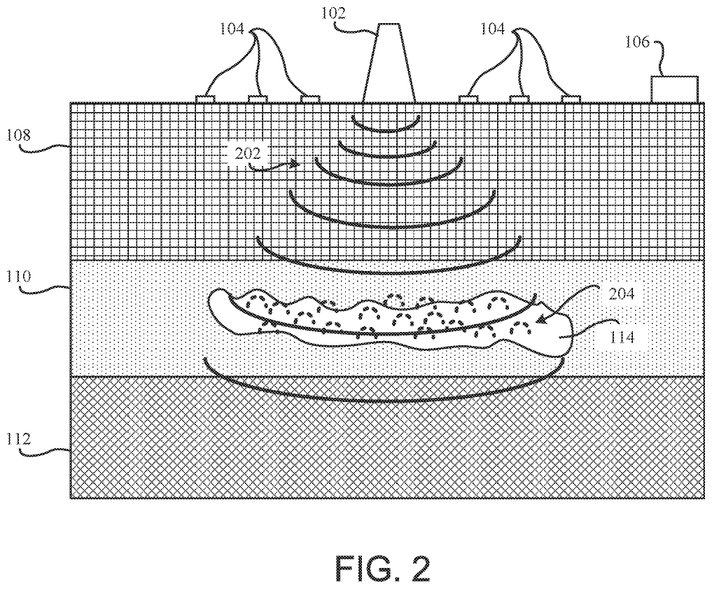

FIG. 1 is a conceptual perspective diagram of a magnetic resonance material locator system 100. FIG. 2 is a conceptual side view diagram of a magnetic resonance material locator system 100. Embodiments of the magnetic resonance material locator system 100 comprise a magnetic field pulse generator 102, one or more acoustic transducers 104, and a controller system 106. The acoustic transducers 104 are located on the surface of the Earth proximate to the magnetic field pulse generator 102.

The disclosed systems and methods for magnetic resonance material locator system 100 will become better understood through review of the following detailed description in conjunction with the figures. The detailed description and figures provide examples of the various inventions described herein. Those skilled in the art will understand that the disclosed examples may be varied, modified, and altered without departing from the scope of the inventions described herein. Many variations are contemplated for different applications and design considerations, however, for the sake of brevity, each and every contemplated variation is not individually described in the following detailed description.

Throughout the following detailed description, a variety of examples for systems and methods for a magnetic resonance material locator system 100 are provided. Related features in the examples may be identical, similar, or dissimilar in different examples. For the sake of brevity, related features will not be redundantly explained in each example. Instead, the use of related feature names will cue the reader that the feature with a related feature name may be similar to the related feature in an example explained previously. Features specific to a given example will be described in that particular example. The reader should understand that a given feature need not be the same or similar to the specific portrayal of a related feature in any given figure or example.

The following definitions apply herein, unless otherwise indicated.

“Substantially” means to be more-or-less conforming to the particular dimension, range, shape, concept, or other aspect modified by the term, such that a feature or component need not conform exactly. For example, a “substantially cylindrical” object means that the object resembles a cylinder, but may have one or more deviations from a true cylinder.

“Comprising,” “including,” and “having” (and conjugations thereof) are used interchangeably to mean including but not necessarily limited to, and are open-ended terms not intended to exclude additional elements or method steps not expressly recited.

Terms such as “first”, “second”, and “third” are used to distinguish or identify various members of a group, or the like, and are not intended to denote a serial, chronological, or numerical limitation.

“Coupled” means connected, either permanently or releasably, whether directly or indirectly through intervening components. “Secured to” means directly connected without intervening components.

“Communicatively coupled” means that an electronic device exchanges information with another electronic device, either wirelessly or with a wire based connector, whether directly or indirectly through a communication network 108. “Controllably coupled” means that an electronic device controls operation of another electronic device.

Returning to FIG. 1, the magnetic field pulse generator 102 and the one or more acoustic transducers 104 of the magnetic resonance material locator system 100 are located on a portion of the Earth's surface that is of interest. One skilled in the arts appreciates that the operator is interested in determining what substances lie below the surface of the Earth, and will be determining what substances are present using an embodiment of the magnetic resonance material locator system 100.

In the simplified conceptual example, assume that the investigated portion of the Earth's surface has a top layer 108, a middle layer 110, and a lower layer 112. Further, assume that the middle layer 110 has, or is made of, a substance of interest 114 that the operators of the magnetic resonance material locator system 100 are interested in locating, preferably with digging precision. Here, locating an underground substance with digging precision is defined as determining the location of the substance of interest 114 with sufficient accuracy so that if excavation and/or mining is performed, the excavation and/or mining can be accurately and reliably directed to the substance of interest 114.

FIG. 2 is a conceptual side view diagram of a magnetic resonance material locator system 100, wherein the magnetic field pulse generator 102 is illustrated as having emitted a magnetic pulse 202 downward through the Earth's surface 108, 110, 112. The magnetic pulse 202 is defined by a predefined duration and a predefined amplitude or magnitude. Timing, duration and amplitude of the magnetic pulse 202 is managed by the controller system 106.

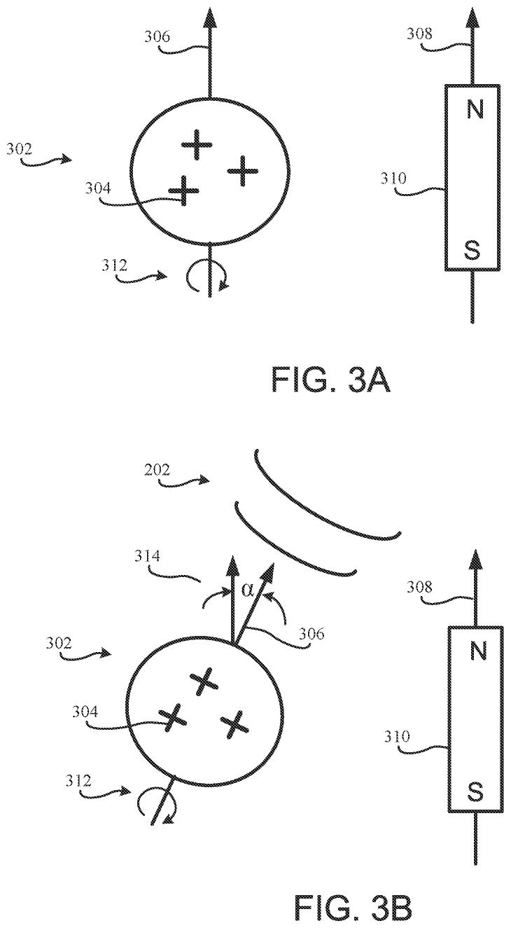

For this simplified conceptual illustrative example, assume that the substance of interest 114 has a material having atoms with a plurality of atomic nuclei where an electric field is established by nuclear charge distribution from adjacent ions and electrons and the magnetic field is established by precession protons and neutrons. FIG. 3A is a conceptual diagram of the atomic nuclei 302 an atom with three protons 304 generating a net magnetization 306. The Earth's magnetic field 308 is conceptually represented by the illustrated magnet 310. The atomic nuclei protons 304 can be viewed as generating a spinning current 312 that generates a quantum magnetic field 306. Here, the atomic nuclei protons 304 act like a tiny magnet that interacts with the vector field of the Earth's magnetic field 308 causing the orientation of the rotational axis of the atom 302 to align with the stronger magnetic field 308 of the Earth.

FIG. 3B is a conceptual diagram of the atomic nuclei 302 with three protons 304 with the magnetic field 306 magnetically realigned in response to magnetic interaction with the generated magnetic field pulse 202 (see also FIG. 2) and the Earth's magnetic field 308. Where the position of the net magnetization from the nucleus depends on the geolocation of the substance 114 in response to the Earth's magnetic field produced from the core of the Earth. Here, the magnetic field 306 interacts with both the Earth's magnetic field 308 and the magnetic pulse 202 generated by the magnetic field pulse generator 102 located on the surface of the Earth. When the magnetic pulse 202 is applied to the substance of interest 114, the magnetic field 202 will cause the atomic nuclei protons 304 with a nonzero spin to precess around the magnetic fields 202, 308. The orientation of the rotational axis of the atom 302 precesses to align, in part, with the magnetic pulse 202. Precession is a change in the orientation of the rotational axis of a rotating body. In an appropriate reference frame, precess can be defined as a change in the first Euler angle, whereas the third Euler angle defines the rotation itself.

A zero spin for protons and neutrons occurs if the atomic mass and proton number that are both even, that is, both the protons and neutrons are even in number. A zero spin nuclei means that nuclear magnetic resonance does not work to cause a net magnetization vector inside the nucleus of atoms.

However, nuclei that have an odd number of protons and either an even or odd number of neutrons, or that has nuclei with an even number of protons and an odd number of neutrons, have a nonzero spin. These nuclei can be identified and located with embodiments of the magnetic resonance material locator system 100 depending on the needed strength and duration of the induced magnetic field 306. Such nuclei will undergo precession to change the orientation of the rotational axis of the atom 302 to align, in part, with the magnetic pulse 202. Conceptually, FIG. 3B illustrates the precession by the angle α.

When the magnetic pulse 202 is no longer present in the substance of interest 114, the atomic nuclei 302 return to their original alignment induced by the Earth's magnetic field 308. The attenuating vibratory motion generates phonons 304. The generated acoustic modes that are particular to each substance that vibrates at the optimal strength from the absorbed magnetic fields or absorbed magnetic and absorbed electric fields into vibratory states of molecules and ions generates a strong enough vibration that the phonon energy, in part, moves upward towards the surface of the Earth. Accordingly, the substance of interest 114 is located with digging precision by the predetermined magnetic field generated from the core of the Earth that creates the magnetic field vector through the subterranean Earth. The magnetic pulse generator will incite the various substances Fourier acoustic modes. In the various embodiments, substances that have atoms defined by a nonzero spin can be detected by the use of nuclear magnetic resonance that is absorbed into one of the natural frequency modes of ions or molecules that are in MHz resonate frequencies.

Identified resonance peak frequencies, interchangeably referred to herein as a phonon response frequency, in some precious metals such as copper, gold, and silver, and other metals may be saved in a frequency response database 518. These phonon response frequencies are unique to each substance. The phonon response frequencies are used by the magnetic resonance material locator system 100 to identify the substance of interest 114. When a propagating electromagnetic wave (such as the magnetic pulse 202) propagates through the medium that is close to the natural lattice vibration of the lattice, the energy gets absorbed and is converted to natural lattice vibrations in MHz frequencies. This absorption can apply to magnetic fields, and to electromagnetic waves. Then knowing that the structure is in the same frequency as the nuclear magnetic resonance when tuned by the magnetic pulse generator can radiate the phonon energy into lattice vibrations for each substance that may be detected by a transducer 104 at the surface.

A phonon, in condensed-matter physics, is a unit of vibrational energy that arises from oscillating atoms within a crystal. Phonons are interchangeably referred to herein as acoustic energy or phonon energy. Phonons can be detected by the acoustic transducers 104. A phonon is a definite discrete unit or quantum of vibrational mechanical energy, just as a photon is a quantum of electromagnetic or light energy. Phonon energy is related to the frequency of the sound waves E=hf and the phonon momentum is related to the wavelength of the sound waves p=h/λ. Sound waves with wavelengths much longer than the lattice constant of a crystal, are described by the wave equation.

For example, a pure diamond crystal lattice within range of the magnetic pulse, [symbol] and in the Earth's magnetic field vector [symbol] [symbol] , where the orientation to [symbol] to the structure can change the local fields and the effective magnetic field [symbol] . However, for a crystalline structure that is a nonmetal the required resonant vibration frequency does not depend on orientation of the applied total vector fields from the Earth's magnetic field [symbol] , magnetic pulse [symbol] , and M the vector sum of the magnetic dipole moments. At a distance of 0.1 nm (1 Å) from a nucleus of moment 1 nuclear magneton, the classical local field is ˜0.5 mT. The effective magnetic field in the nuclei are modified to account for the Earth's magnetic field vector. A macroscopic equation of materials is described below in Equations (1) and (2).

[symbol]

= [symbol] +μₒμₜ [symbol] +μₒμₜ [symbol] , and (1)

[symbol]

=χₘ( [symbol] + [symbol] ) (2)

Equation (1) equates the magnetic field vector at a bare nucleus site. Equation (1) and (2) applies to ferromagnetic substance (which is commonly found in iron, nickel, and cobalt, or nonferromagnetic substances which can be diamond, oil, water, lithium and other rare substances who atomic structure has paired electron spins. The classification of the magnetic properties of the materials are either paramagnetic where χₘ has a (−) sign, diamagnetic where χₘ has a (+) sign; or ferromagnetic where ×ₘ>>1 and is nonlinear and is based on the history of the substance of interest 114.

Table 1 gives the parameters of Equations (1) and (2).

TABLE 1
Parameters of equation (1) and (2)

| Description | Symbol | Units |
|---|---|---|
| Effective magnetic field vector for a bare | [symbol] | T |
| nucleus | | |
| Earth’s magnetic field vector disclosed in | [symbol] , [symbol] | T, A/m |
| simulation | | |
| Magnetic permeability | μₒ | H/m |
| Relative permeability | μᵣ | Dimensionless |
| | | and complex |
| Magnetic susceptibility due to electron density, | χₘ | Factor |
| shielding, and unpaired orbital electrons. | | (Dimensionless) |
| Magnetic pulse vector | [symbol] | A/m |
| Vector sum of the magnetic dipole moments of | [symbol] | A/m |
| the atoms contained in a unit volume | | |

The quantum energy given to the nuclei for a bare nucleus gives a result in accordance with Equation (3).

E=γℏ [symbol] m. (3)

Where in Equation (3) the eigenvalues of m, takes the (2I+1) values from +I through +(I−1) to −(I−1), −I. Hence Equation (3) gives the possible energy of the nuclei in atoms. When I has a spin >½ (which most elements has), results in a quadrupole moment that can have both an electric interaction to neighboring atoms, molecules, ions and orbital and spin motion of electrons; and a magnetic interaction to neighboring nuclei, and induced magnetic field by orbital electrons, and induced magnetic fields by conduction electrons. The electric field can be produced by adjacent ions and electrons charge distribution and the precession nuclei produce the magnetic fields. The magnetic and electric fields create the spin-lattice interaction as also the spin-spin interaction, that is primarily magnetic in origin producing the interaction, which is by electric and magnetic fields or only magnetic fields throughout the solid or liquid. When a purely magnetic spin-spin interaction is in place with each named substance results in the interaction that generates a spin resultant temperature throughout the lattice, or generally speaking substance from magnetic dipoles. Table 2 has a full description of the variables for Equation (3).

TABLE 2
Parameters for the bare nucleus

| Description | Symbol | Units |
|---|---|---|
| Quantum energy at a nucleus site | E | J |
| Magnetogyric ratio (ratio between the magnetic | γ | rad/sT |
| and mechanical moments; varies from one | | |
| nucleus to another) | | |
| Planks constant | h | Js |

Equation (4) gives the quantum phonon energy in a solids lattice that is either crystalline, partially ordered, or non-crystalline structure. Table 3 defines the parameters in Equation (4).

Eₙ=(n+½)ℏω. (4)

TABLE 3
Parameters of Equation (3) for the phonon vibration energy

| Description | Symbol | Units |
|---|---|---|
| Quantum energy of the vibration | Eₙ | J |
| Eigenvalues of possible quantization of energy | n | Integer |
| for phonons | | |
| Planks constant | h | Js |
| vibration oscillation frequency | ω | rad/s |

If equate the energies in equation (3) and (4) are equated, and then solved for frequency, will result as the quantum frequency that each unique substance has. Each substance possesses a unique frequency or a combination of frequencies that can be used to identify the materials. Equation (5) applies either to metals or nonmetallic solids, that has the crystalline structure in elements, minerals, or organic compounds. Where the word minerals refer to a solid inorganic substance of natural occurrence.

$$ω = \frac{γ \vec{Be} ff m}{( n + 1 / 2 )} . \qquad ( 5 )$$

When the nuclear magnetic resonance from the nuclei in the substance of interest 114 is no longer present, the nuclei that have been precessed by the magnetic pulse 202 return to their original orientation. The returning to the original orientation results in emission of acoustic energy 204. A portion of the acoustic energy 204 travels upward towards the surface of the Earth. When the acoustic energy 204 reaches the surface of the Earth in proximity to the one or more acoustic transducers 104, the acoustic transducers 104 senses the acoustic energy 204 and generate an electric signal corresponding to the detected acoustic energy 204. This signal is returned to the controller system 106.

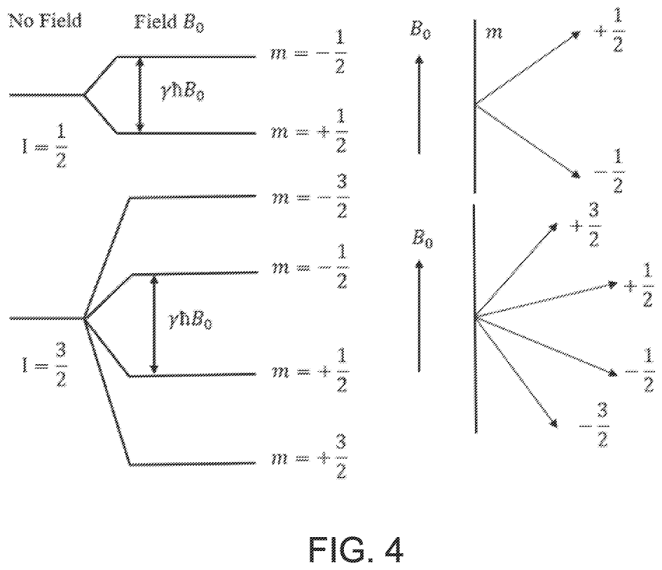

FIG. 4 is a diagram illustrating magnetic properties and space quantization of nuclei influenced by a magnetic field.

The natural frequencies of partially ordered solids will have its own set of unique absorbed nuclear magnetic resonance (NMR) frequencies that are required to convert the quantum energy into phonon lattice vibrations. The complex permeability and complex permittivity imaginary resonance peaks are the macroscopic view of atoms. The resonance peaks determine the absorption frequency for the nuclear magnetic resonance converts into vibration waves that are transmitted upward to the surface.

The frequency modes of an amorphous structure may be approximated by simulation, particularly for some amorphous solids with only tetrahedral bonded random networks. The imaginary component in the complex permeability or complex permittivity are the macroscopic view of how fields interact with the atoms. When the complex permeability or complex permittivity has resonant imaginary peaks, the required calculated nuclear magnetic resonance found at the controller system 106 discovers the absorbed electric and magnetic or only magnetic fields into lattice waves that is dependent on the structure of the non-crystalline solid.

It is rare to see a quantum relationship with phonons in liquids. However, a magnetic pulse can cause a non-crystalline liquid with nonzero spin to precess the nuclei. The ionic coupling in certain substances with spin I>½ can cause the ionic atoms to vibrate to the electric component of atoms. When a spin I=½, the precession nuclei interaction to the neighboring atoms is purely magnetic. If the complex permeability or complex permittivity imaginary component has resonant peaks then the nuclear magnetic resonance, if calculated at the controller system 106 to this resonant frequency has the ability to absorb the fields into lattice vibrations. Things like fresh water, crude oil, and other liquid substances with a nonzero spin can be detectable through a solid medium to an acoustic transducer on the surface.

Having a database of Earth substance frequencies based on one of the modes of that substance and with the Earth's magnetic field can be used to identify a substance and locate the substance depth beneath the surface using a computer (such as the controller system 106). Essentially, with a knowledge of the magnetic field variation and the magnetic field strength at the surface of the metallic core and the position and diameter of the core will generate the computation needed to know with close certainty the Earth magnetic field [symbol] at the approximate location of substance of interest 114 sought to give digging precision. The use of Equation (1) and (2) is for both ferromagnetic and nonferromagnetic substances, which can give for each particular substance sought the required value for [symbol] . The Earth's magnetic field [symbol] can be known. Leaving the value required to identify each Earth substance as [symbol] . Plugging these all together will locate and identify the substance of interest 114. These can give the required magnetic pulse Ho to find each element of the substance of interest 114 that can be metal or nonmetallic, in solid, powder, or liquid form. Also, the substance of interest 114 that can be searched can be organic compounds, or inorganic compounds of a wide variety of substances to induce the precession of nuclei at one of the resonant modes. Refer to Equation (6).

[symbol]

= [symbol] μₒμₜ [symbol] −μₒμₜ [symbol] (6)

When the substance resonates to the magnetic pulse and magnetic field of the Earth, use of a computer can be used to create a database of phonon response frequencies for various minerals and other substances beneath the surface of the Earth. Since the magnetic field of the Earth is unique to the depth of the solid or liquid material will change the resonate mode. The required resonate mode will correlate to the strength of the Earth's magnetic field vector to give the location of the sought-after element, organic compound such as oil, and inorganic compound such as metals, alloys, and ores. The substance of interest 114 are preferably solid, powder, or in liquid form in order for embodiments of the magnetic resonance material locator system 100 to utilize the vibration to detect a series of acoustic transducers 104 at the Earth's surface.

Summarizing, elements, organic compounds and minerals, either in solid, powder, or liquid form; either in a crystalline lattice structure, partially ordered structure, and amorphous (that has a random network of atoms) that has a nonzero precession can be utilized by a magnetic pulse to precess nuclei. When the spin of the substance has an I=½ vibrates in one of the modes of the natural quantum oscillation frequency that has magnetic coupling that is only magnetic. The precession magnetic fields are at the same frequency of vibrating structures. When substances have a spin I>½ results in quadruple that gives electric and magnetic energy transfers to the atoms, molecules, or ions, and by orbital and spin motion of electrons. When the modes are matched to the nuclear magnetic resonance results in absorbed energy in forms of vibrations. In terms of the complex permeability or the complex permittivity, the resonant imaginary component determines the modes of the atoms, ions, or molecules. The Earth's magnetic field gradient is the means to get digging precision when solid Earth is the medium for the traveling acoustic energy to an acoustic transducer 104.

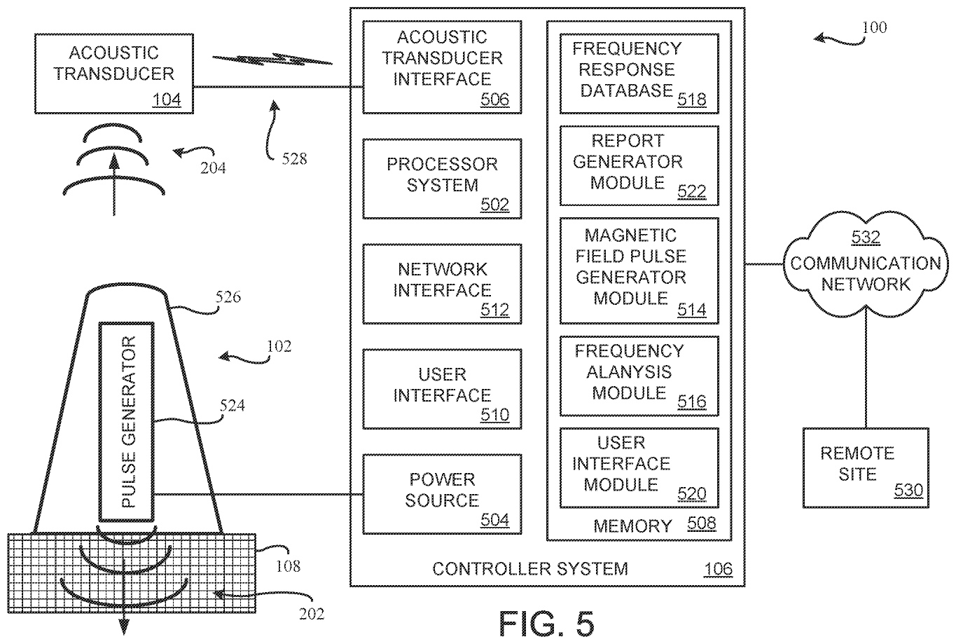

FIG. 5 is a block diagram of an embodiment of the magnetic resonance material locator system 100. Embodiments of the controller system 106 comprises a processor system 502, a power source 504, an acoustic transducer interface 506, a memory 508, an optional user interface 510, and an optional network interface 512. The memory 508 includes regions for storing the magnetic pulse generator module 514, the frequency analysis module 516, a frequency response database 518, an optional user interface module 520, and an optional report generator module 522.

In some embodiments, the magnetic pulse generator module 514, the frequency analysis module 516, the user interface module 520, and the report generator module 522 may be integrated together, and/or may be integrated with other logic. In other embodiments, some or all of these memory and other data manipulation functions may be provided by using a remote server or other electronic devices suitably connected via the Internet or otherwise to a client device. In some embodiments, the frequency response database 518 may reside remotely and/or may include other data of interest. Other controller systems 106 may include some, or may omit some, of the above-described media processing components. Further, additional components not described herein may be included in alternative embodiments.

For example, in some embodiments, the controller system 106 may be a distributed system. The processor system 502 and the memory 508 may be remotely located, and the acoustic transducer interface 506 and the network interface may be local to the magnetic field pulse generator 102 and the acoustic transducers 104. The signal corresponding to the detected phonons would then be communicated to the remotely located processor system 502 and memory 508 for analysis.

The magnetic field pulse generator 102 comprises a pulse generator 524 and an optional magnetic shield 526. The pulse generator 524 generates the magnetic pulse 202 that is directed downward into the surface of the Earth. In an example embodiment, the pulse generator 524 employs one or more coils of wire made of a suitable conducting material. Any suitable magnetic field pulse generator 524 now known or later developed are intended to be within scope of this disclosure and to be protected by the accompanying claims.

An optional electromagnetic magnetic shield 526 surrounds the magnetic field pulse generator 524. The electromagnetic magnetic shield 526 constrains, or substantially constrains, the magnetic field of the magnetic pulse 202 to remain within the interior region of the electromagnetic magnetic shield 526, preferably for safety reasons. Here, if an operator with an electronic device, such as a heart pacemaker or the like, and/or another sensitive electronic device, are in the vicinity of the magnetic resonance material locator system 100 during magnetic pulse generation, the electromagnetic magnetic shield 526 will prevent, or substantially prevent, transmission of potentially harmful magnetic radiation from harming any nearby people and/or electronic devices. In an example embodiment, the electromagnetic magnetic shield 526 is made of a magnetic shielding material and is generally arranged in a cone-like shape. However, alternative embodiments may use any suitable shape for the electromagnetic magnetic shield 526. Configurations and/or materials for the electromagnetic magnetic shield 526 now known or later developed are intended to be within the scope of this disclosure and to be protected by the accompanying claims.

The power source is coupled to pulse generator 524. The duration of power and the amount of power (watts, current and/or voltage) provided by the power source that is used by the pulse generator 524 to generate the magnetic field pulse is controlled by the processor system 502 executing the magnetic field pulse generator module 514. The power may be provided by any suitable power source, such, but not limited to a generator, a battery system, a charged capacitor, solar panels, and/or the electric grid.

The user interface 510 may be configured in one embodiment to receive the specification from the operator of the magnetic resonance material locator system 100 by receiving information provided by a conventional input device (not shown) or from a specially fabricated input device (not shown). For example, but not limited to, user interface 510 may be configured to receive information from the operator via a conventional keyboard device coupled. Other examples of input devices include a conventional touch pad, touch screen, mouse, rocker switches or other types of buttons. One skilled in the art will appreciate that the user interface 510 may be implemented using well known components and techniques employed in the art of receiving input data. Detailed operation of the individual components (not shown) used to implement the user interface 510 are not described in detail herein, other than to the extent necessary to understand the operation and functioning of the magnetic resonance material locator system 100. Furthermore, the well-known components used to implement the user interface 510 are too numerous to conveniently describe in detail herein. Therefore, any embodiment of the user interface 510 configured to operate the magnetic resonance material locator system 100 may be implemented without departing substantially from the functionality and operation of embodiments of the magnetic resonance material locator system 100. Any such variations in the user interface 510 are intended to be within the scope of this disclosure and to be protected by the accompanying claims.

In practice, the operator specifies parameters, via the user interface 510, for the desired magnetic pulse that is to be generated by the pulse generator 524. The operator may specify pulse duration and/or pulse amplitude, and optionally a time that the magnetic pulse is to be initiated, in an example embodiment.

The acoustic transducer interface 506 is communicatively coupled to the one or more acoustic transducers 104. The acoustic transducers 104 are configured to detect sounds generated by the phonon energy (the acoustic energy 204) of the nuclei after the magnetic pulse has caused the precession of the nuclei. Example acoustic transducers 104 include microphones, Dynamic Electric Condensers, Ribbons and Piezo-electric crystal types. Any suitable acoustic transducer now known or later developed are intended to be included within scope of this disclosure and to be protected by the accompanying claims.

When the acoustic transducers 104 detect the acoustic energy 204 after generation and transmission of the magnetic pulse 202, the one or more acoustic transducers 104 sense the acoustic energy 204 and generate an electrical signal that is received at the acoustic transducer interface 506. The generated signal 528 may be a wireless signal (Wi-Fi, Bluetooth, etc.) and/or may be a wire-based signal.

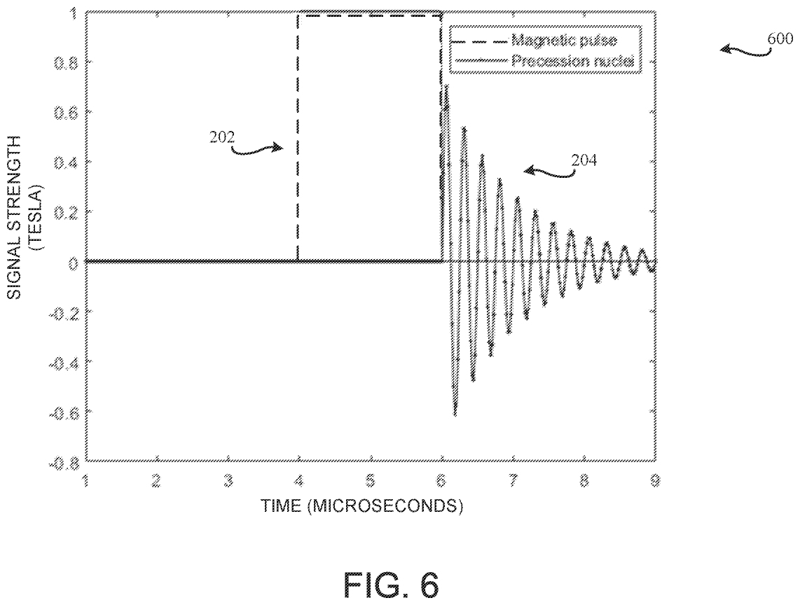

FIG. 6 is a plot 600 of an example plot of signal strength versus time indicating an example magnet field pulse 202 and the phonon response frequency of the detected acoustic energy 204. The example magnetic pulse has a signal strength of one tesla over a duration of two microseconds. After the end of the pulse, the returning acoustic energy 204 that has been detected by an acoustic transducer 104 is analyzed, and may be optionally plotted or graphed in a report.

The processor system 502 (FIG. 5), executing the frequency analysis module 516, analyzes the signals received from the acoustic transducers 104 to determine the frequency and/or frequency components of the acoustic signals. Any suitable frequency domain analysis method, such as but not limited to Fourier transforms, now known or later developed is intended to be within the scope of this disclosure and to be protected by the accompanying claims. The determined frequency and/or frequency components are compared with the phonon response frequencies of known substances. The frequency response database 518 stores information defining the phonon response frequencies of known substances. When a match is made between one of the phonon response frequencies of a known substance and the determined detected phonon response frequency, the substance of interest 114 is identified.

When a matrix of acoustic transducers 104 with known locations are used over a geographic area around the magnetic field pulse generator 102, those acoustic transducers 104 detecting returning acoustic energy 204 may increase the digging precision of collected data, and those acoustic transducers 104 not detecting any acoustic energy 204 can be used to define the extents of the substance of interest 114.

The amplitude of the detected acoustic energy 204 may be used to determine the depth of the substance of interest 114. Accordingly, the processor system 502 executing the frequency analysis module 516 is able to determine the location of the substance of interest 114 with digging precision. The processor system 502, executing the report generator module 522, then generates a suitable report regarding the results of the frequency analysis.

The network interface 512 is configured to communicatively couple the controller system 106 to a remote site 530 via the communication network 532. Data and/or reports may be communicated from the controller system 106 to the remote site for further analysis and/or storage in a suitable memory medium. The communication network 532 is illustrated as a generic communication system. In one embodiment, the communication network 532 comprises a cellular telephone system, such as a radio frequency (RF) wireless system. Accordingly, the controller system 106 includes a suitable transceiver. Alternatively, the communication network 532 may be a telephony system, the Internet, a Wi-fi system, Bluetooth, a near-field communication system, a microwave communication system, a fiber optics system, an intranet system, a local access network (LAN) system, an Ethernet system, a cable system, a radio frequency system, a cellular system, an infrared system, a satellite system, or a hybrid system comprised of multiple types of communication media. Additionally, embodiments of the magnetic resonance material locator system 100 may be implemented to communicate using other types of communication technologies, such as but not limited to, digital subscriber loop (DSL), X.25, Internet Protocol (IP), Ethernet, Integrated Services Digital Network (ISDN) and asynchronous transfer mode (ATM), and 4G/5G wireless networks. Also, embodiments of the magnetic resonance material locator system 100 may be configured to communicate over combination systems having a plurality of segments which employ different formats for each segment that employ different technologies on each segment.

It should be emphasized that the above-described embodiments of the magnetic resonance material locator system 100 are merely possible examples of implementations of the invention. Many variations and modifications may be made to the above-described embodiments. All such modifications and variations are intended to be included herein within the scope of this disclosure and protected by the following claims.

Furthermore, the disclosure above encompasses multiple distinct inventions with independent utility. While each of these inventions has been disclosed in a particular form, the specific embodiments disclosed and illustrated above are not to be considered in a limiting sense as numerous variations are possible. The subject matter of the inventions includes all novel and non-obvious combinations and subcombinations of the various elements, features, functions and/or properties disclosed above and inherent to those skilled in the art pertaining to such inventions. Where the disclosure or subsequently filed claims recite “a” element, “a first” element, or any such equivalent term, the disclosure or claims should be understood to incorporate one or more such elements, neither requiring nor excluding two or more such elements.

Applicant(s) reserves the right to submit claims directed to combinations and subcombinations of the disclosed inventions that are believed to be novel and non-obvious. Inventions embodied in other combinations and subcombinations of features, functions, elements and/or properties may be claimed through amendment of those claims or presentation of new claims in the present application or in a related application. Such amended or new claims, whether they are directed to the same invention or a different invention and whether they are different, broader, narrower, or equal in scope to the original claims, are to be considered within the subject matter of the inventions described herein.

Therefore, having thus described the invention, at least the following is claimed:

1. A method of locating a substance of interest that is below a surface of the Earth, comprising:
generating a magnetic pulse using a magnetic field pulse generator,
wherein the magnetic pulse is directed downward into the surface of the Earth,
wherein the magnetic pulse is defined by a predefined duration and a predefined amplitude, and
wherein phonon energy is emitted by a plurality of nuclei in response to precession induced into the plurality of nuclei by the magnetic field pulse;
detecting the phonon energy with at least one acoustic transducer that is located on the surface of the Earth proximate to the magnetic field pulse generator;
communicating a signal corresponding to the detected phonon energy from the at least one acoustic transducer to a controller system;
analyzing a frequency domain of the signal corresponding to the detected phonon energy at the controller system;
comparing the analyzed frequency domain of the signal with the phonon response frequency for the plurality of different substances at the controller system; and
identifying, at the controller system, a substance when the compared analyzed frequency domain of the signal matches the phonon response frequency for one of the plurality of different substances.

2. The method of claim 1, further comprising:
determining, at the controller system, a location of the identified substance that is below the surface of the Earth,
wherein the determination is based on a specific magnetic field vector of the Earth that is predetermined and is stored in a memory by the controller system with a geolocation of the subterranean Earth, and
wherein the frequency domain of the signal corresponds to the detected phonon energy generated in response to the magnetic pulse generator and Earth's magnetic field vector,
determining depth of the identified substance based on the vibratory modes of a known subterranean substance.

3. The method of claim 2, wherein determining the location of the identified substance further comprises:
determining, at the controller system, a depth of the identified substance based on the analysis of the frequency domain of the signal corresponding to the detected phonon energy.

4. The method of claim 3, wherein a plurality of acoustic transducers are distributed on the surface of the Earth in proximity to the magnetic field pulse generator, wherein a location of each one of the plurality of acoustic transducers are known, and wherein determining the location of identified substance further comprises:
identifying a group of the plurality of acoustic transducers that communicated the signal corresponding to the detected phonon energy from the at least one acoustic transducer, and
determining the extent of the identified substance based on the known locations of the group of the plurality of acoustic transducers that communicated the signal corresponding to the detected phonon energy.

5. The method of claim 4, wherein determining the location of the substance having the plurality of nuclei further comprises:
determining the location of the identified substance with digging precision based on the determined depth and the determined extent of the identified substance.

6. The method of claim 1, wherein the magnetic field pulse generator is surrounded by a magnetic shield, the method further comprising:
constraining a magnetic field of the magnetic pulse within an interior region of the magnetic shield.

7. A magnetic resonance material locator system, comprising:
a magnetic field pulse generator that generates a magnetic pulse that is directed downward into a surface of the Earth, wherein the magnetic pulse is defined by a predefined duration and a predefined amplitude;
at least one acoustic transducer that is configured to detect phonon energy; and
a controller system controllably coupled to the magnetic field pulse generator and communicatively coupled to the at least one acoustic transducer,
wherein the phonon energy is emitted by a plurality of nuclei in response to precession induced into the plurality of nuclei by the magnetic field pulse, and
wherein the at least one acoustic transducer emits a signal to the controller system that corresponds to the detected phonon energy.

8. The magnetic resonance material locator system of claim 7, wherein the controller comprises:
a processor system; and
a memory communicatively coupled to the processor system,
wherein a frequency response database resides in the memory stores a unique phonon response frequency for a plurality of different substances,
wherein the processor system analyzes a frequency domain of the signal corresponding to the detected phonon energy,
wherein the processor system compares the analyzed frequency domain of the signal with the phonon response frequency for the plurality of different substances, and
wherein a particular substance is identified when the analyzed frequency domain of the signal matches the phonon response frequency of one of the plurality of different substances.

9. The magnetic resonance material locator system of claim 7, wherein the magnetic field pulse generator comprises:
a pulse generator controllably coupled to the controller and configured to output the magnetic pulse,
wherein the controller controls an amplitude of the output magnetic pulse and a duration of the magnetic pulse.

10. The magnetic resonance material locator system of claim 9, wherein the magnetic field pulse generator further comprises:
a magnetic shield,
wherein the magnetic shield constrains the magnetic pulse to remain within the magnetic field pulse generator.
